(19) United States
(12) Patent Application Publication
(10) Pub. No.: US 2025/0201622 A1
(43) Pub. Date: Jun. 19, 2025

(54) SUPPORT STRUCTURES FOR SEMICONDUCTOR SUBSTRATES

(71) Applicant: Intel Corporation, Santa Clara, CA (US)

(72) Inventors: Sonja Koller, Lappersdorf (DE); Pouya Talebbeydokhti, Mesa, AZ (US); Vishnu Prasad, Munich (DE); Stefan Reif, Munich (DE); Carlton Hanna, Santa Clara, CA (US); Thomas Wagner, Regelsbach (DE)

(21) Appl. No.: 18/539,351

(22) Filed: Dec. 14, 2023

(51) Int. Cl. H01L 21/687; H01L 21/673; H01L 21/683

(52) U.S. Cl. CPC H01L 21/6875; H01L 21/6734; H01L 21/6838; H01L 21/68742

(57) ABSTRACT

A semiconductor tool having a support assembly for holding a semiconductor panel in a level position during an assembly process is able to remediate the warpage that may be present in the semiconductor panel. The support assembly may be equipped with a plurality of height-adjustable support pillars in the form of an array that is positioned below the semiconductor panel to provide a level position. The support pillars may be activated by a controller to engage or land on dedicated landing features or pads formed on the semiconductor panel or on suitable landing features that may be found in a semiconductor design layout and provide a dual use.

### BACKGROUND

For integrated circuit design and fabrication, the need to improve performance and lower costs are constant challenges. The continuing trend towards miniaturization, i.e., a reduction in the form factor for a printed circuit board with a semiconductor package and various other components, may lead to lower material costs, as well as improved performance with more compact designs. Further cost savings may potentially be realized by building dies on semiconductor panels rather than semiconductor wafers.

By using a rectangular panel as a substrate, panel-level fan-out technology offers the potential for lower production cost due to a higher area utilization ratio of the carrier and better economical manufacturing, especially for large packages. Presently, there are efforts to develop panel-level packaging technology that will follow a roadmap that will lead to increasingly larger panels, e.g., 610 mm by 650 mm panels and larger. However, there may be physical limits in panel-level packaging that may prevent the use of larger panels, such as warpage.

The panel warpage may be due to several factors, including the shrinkage of the epoxy molding compound during the post-curing stage, process-induced stresses, and the mismatch in the coefficients of thermal expansion (CTE) of the individual encapsulation materials and the carrier. Additionally, in the production and application of this technology, panel warpage may result in various technical issues, e.g., the panel-level warpage may exceed the handling capability of the processing tools, rendering processing operations extremely difficult to align and resulting in lower yields. Therefore, it is critically important to provide solutions for remediating the effects of panel warpage during manufacturing and assembly processes for panel-level packaging.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a semiconductor panel and support assembly arrangement according to an aspect of the present disclosure;

FIG. 2 shows an exemplary representation of another view of a semiconductor panel and support assembly arrangement according to an aspect of the present disclosure;

FIGS. 3A and 3B show exemplary representations of support pillar configurations according to aspects of the present disclosure;

FIG. 4 shows an exemplary representation of yet another view of a semiconductor panel and support assembly arrangement according to an aspect of the present disclosure;

FIG. 5 shows an exemplary representation of a support pillar according to an aspect of the present disclosure;

FIG. 6 shows an exemplary representation of another support pillar according to another aspect of the present disclosure;

FIG. 7 shows an exemplary representation of a lifting actuator according to an aspect of the present disclosure;

FIG. 8 shows an exemplary representation of another lifting actuator according to another aspect of the present disclosure;

FIGS. 9A, 9B, 9C, and 9D show exemplary representations of landing pads according to an aspect of the present disclosure;

FIG. 10 shows an exemplary representation of a support pillar and a landing pad according to another aspect of the present disclosure;

FIGS. 11A, 11B, 11C, 11D, and 11E show exemplary representations of configurations for support pillars and landing pads according to an aspect of the present disclosure; and

FIG. 12 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a present support assembly may be able to hold a semiconductor panel in a level position during an assembly process by being equipped with a plurality of height-adjustable support pillars that are positioned below the semiconductor panel. The support pillars may engage or land on dedicated landing pads or other landing structures that may be “re-used” or have a dual use (i.e., have another function in a semiconductor product being formed in the semiconductor panel).

In an aspect, the present support assembly may be integrated into a support platform (e.g., either a round or rectangular chuck) of a semiconductor assembly tool or may be a unit that is retrofitted onto the support platform of an existing semiconductor assembly tool. In another aspect, the support pillars may be placed in a regular grid array, an array with variable x-y positions, or a “mixed” array with regular and variable positions for the support pillars. In a further aspect, the heights (i.e., z-direction) of each support pillar may be individually controllable (e.g., by a lifting actuator). The z-direction adjustment may be based on pre-measured warpage measurements for the semiconductor panel. The specified support pillars may be activated (i.e., the height being adjusted to press against the semiconductor panel), or remain inactive (i.e., the height being so low that they are not touching the semiconductor panel). In addition, the activation of the support pillars may be controlled by adjusting the pressure or suction applied on an individual support pillar or group of support pillars.

The present disclosure provides a support assembly disposed in a semiconductor processing tool, with the support assembly having a plurality of support pillars, and each of the plurality of support pillars has a body with a movable pin with an upper portion for engaging a semiconductor panel. In an aspect, the support assembly is coupled to a controller, and the controller is configured to enable each of the movable pins to move individually in a vertical direction to engage a plurality of landing features on the semiconductor panel.

The present disclosure is also directed to a method that includes providing a semiconductor tool with a support platform with a plurality of support pillars embedded in the support platform and disposing a semiconductor panel on the support assembly. Each of the plurality of support pillars includes a body with a movable pin with an upper portion that engages the semiconductor panel, and the upper portion of the movable pin is aligned with a landing feature on the semiconductor panel. The method provides a level surface to perform an assembly step using the semiconductor tool.

The present disclosure is further directed to a semiconductor tool having a support platform with a support assembly. The support assembly includes a plurality of support pillars and each of the plurality of support pillars has a body with a movable pin with an upper portion for engaging a semiconductor panel. In an aspect, the semiconductor tool includes a controller coupled to the support assembly to enable each of the movable pins to move individually in a vertical direction to engage the semiconductor panel, and the controller is provided with a warpage profile for the semiconductor panel and activates lifting actuators to move the movable pins in a vertical direction to engage a plurality of landing features on the semiconductor panel according to the warpage profile to provide a level position.

The technical advantages of the present disclosure include, but are not limited to:
(i) providing a support platform with a support assembly that may provide a level positioning during an assembly processing step and thereby improve yields;
(ii) providing a support platform with a support assembly that may compensate for warpage in a semiconductor panel caused by upstream processing steps;
(iii) providing a support platform with a support assembly that may be individualized for a specific semiconductor product and may be adjusted to accommodate design changes; and
(iv) providing a support platform that may be used with increasing panel sizes.

To more readily understand and put into practical effect the present support assembly and methods, which may provide improved support for semiconductor panels, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

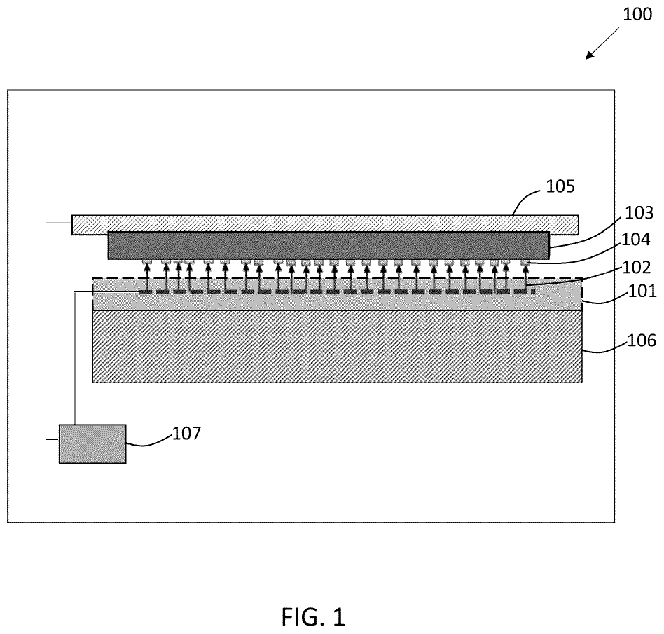

FIG. 1 shows an exemplary representation of a semiconductor panel and support assembly arrangement according to an aspect of the present disclosure. In this aspect, a semiconductor tool 100 may have a support assembly 101, which may also be referred to as a panel support assembly, that includes a plurality of support pillars 102. The semiconductor tool 100 may be, for example, a die attachment tool that may be using a surface mount technology or a solder bumping tool. The support assembly 101 may be an integrated part of a support platform 106, which may be a chuck, or a retrofit unit placed on the support platform 106. In another aspect, the support platform or chuck 106 may have several levels and the support assembly 101 may be the top level.

In addition, a semiconductor panel 103 having a plurality of landing features 104 may be held in a movable frame 105 and disposed in the semiconductor tool 100 on the plurality of support pillars 102. As shown in FIG. 1, the plurality of support pillars 102 may be aligned with and positioned below the plurality of landing features 104. The use of landing features 104 is generally preferred to avoid the risk of the support pillars 102 causing damage to the semiconductor panel 103. The semiconductor panel 103 may have a size in a range of approximately 300×300 mm² to 700×700 mm². A typical panel size may be approximately 610×610 mm² and have approximately 420,000 support pillars when positioned in a regular grid array.

In an aspect, the movable frame 105 may be used to provide a downward force on the semiconductor panel 103 to promote contact between the landing features 104 and the support pillars 102 and may also be used for alignment therebetween. In another aspect, the support platform or chuck 106 may be movable and may also be used for alignment.

In an aspect, a controller 107 may be coupled to the support assembly 101 and may also be coupled to the movable frame 105 as shown in FIG. 1. The controller 107 may be configured to enable each support pillar 102, which includes a body and a movable pin (which are shown below), to move individually in a vertical direction to engage a plurality of landing features 104 on the semiconductor panel. The controller 107 may be provided with a warpage profile for the semiconductor panel 103 and activates lifting actuators to move the movable pins, which each have an upper portion and support surface (both shown below), in a vertical direction to position the upper portion of the movable pin to engage the plurality of landing features 104 on the semiconductor panel 103 according to the warpage profile to provide a level position. A warpage profile may be obtained from a direct measurement or pre-calculated based on simulations (including a combination of both) and may provide data on where support pillars may be located. It should be understood that it is within the scope of the present disclosure to have a present controller that may be part of a semiconductor tool or part of a production control system. The present controller may adjust the pressure applied to an individual or group of present support pillars.

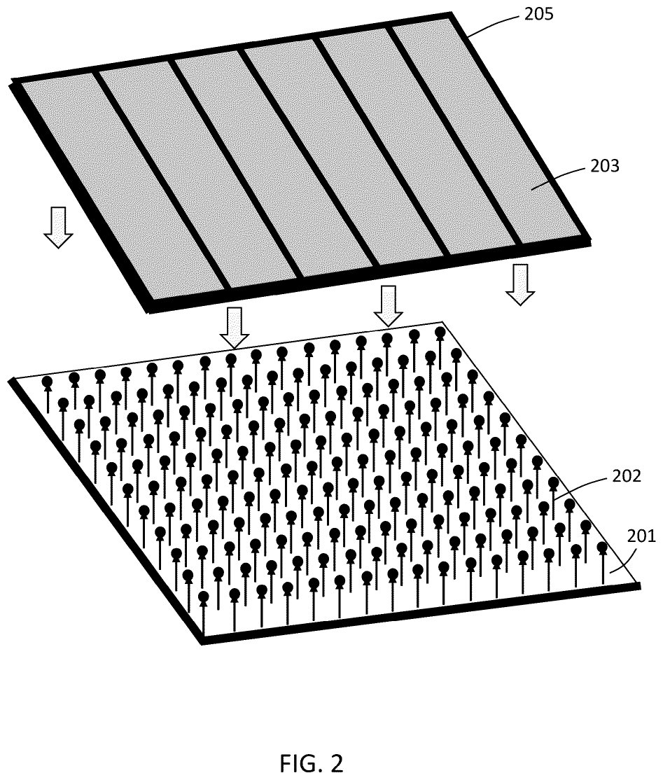

FIG. 2 shows an exemplary representation of another view of a semiconductor panel and support assembly arrangement according to an aspect of the present disclosure. In this aspect, a support assembly 201 may be provided with a plurality of support pillars 202. The plurality of support pillars 202 may be configured in a regular grid array as shown or in an array with variable x-y positions (not shown) or a “mixed” array with regular and variable positions for the support pillars (not shown). In an aspect, the plurality of support pillars in a regular grid array may have a pitch (i.e., pillar to pillar) as small as 300 μm, and a “normal” pitch of approximately 1 mm. In addition, a semiconductor panel 203 may be positioned in a movable frame 205, which may be used to position the semiconductor panel 203 on the plurality of support pillars 202, as shown in FIG. 1.

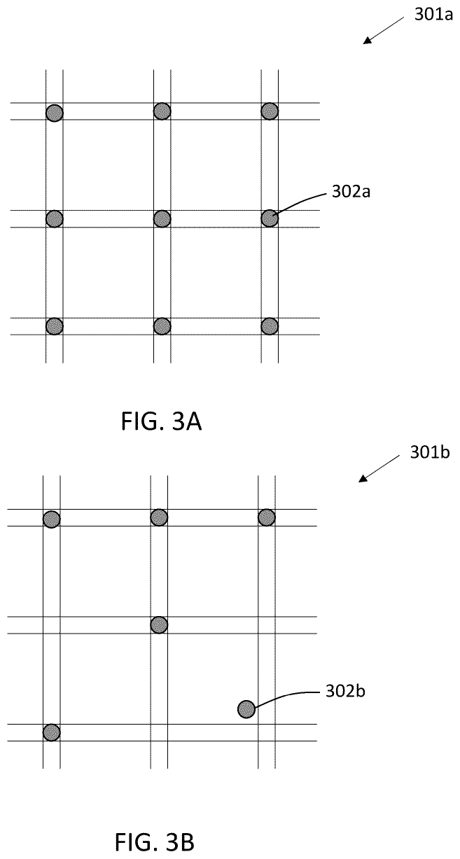

FIGS. 3A and 3B show exemplary representations of support pillar configurations according to aspects of the present disclosure. In FIG. 3A, a partial view of a support assembly 301a is shown with a plurality of support pillars 302a that are configured in a regular grid array, while in FIG. 3B, a partial view of a support assembly 301b is shown with a plurality of support pillars 302b that are configured in an “irregular” grid array. Such irregular grid arrays may have support pillars that are not spaced apart equally and not aligned in a straight line.

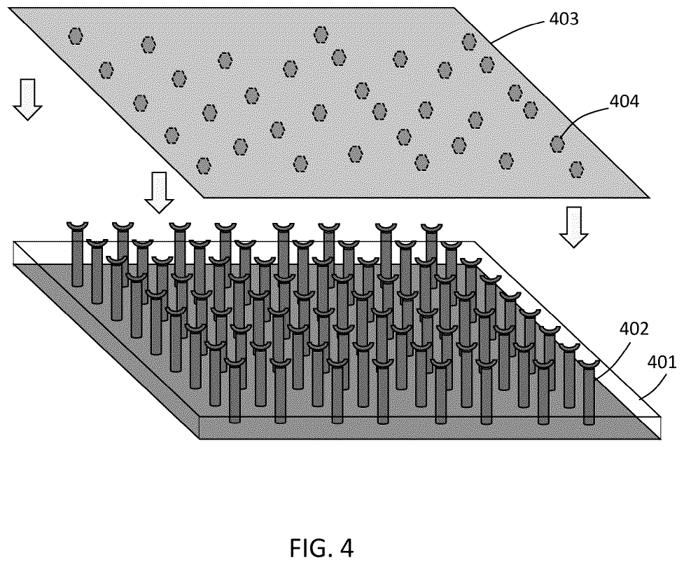

FIG. 4 shows an exemplary representation of yet another view of a semiconductor panel and support assembly arrangement according to an aspect of the present disclosure. In this aspect, a support assembly 401 may be provided with a plurality of support pillars 402. The plurality of support pillars 402 may be configured with a regular grid array as shown, while a semiconductor panel 403 may be configured with an irregular grid array of landing features 404. In this semiconductor panel and support assembly arrangement, a controller (not shown) may activate those support pillars 402 that correspond to the locations of the irregular grid array of landing features 404, while the remaining support pillars are inactive, i.e., in a lowered position.

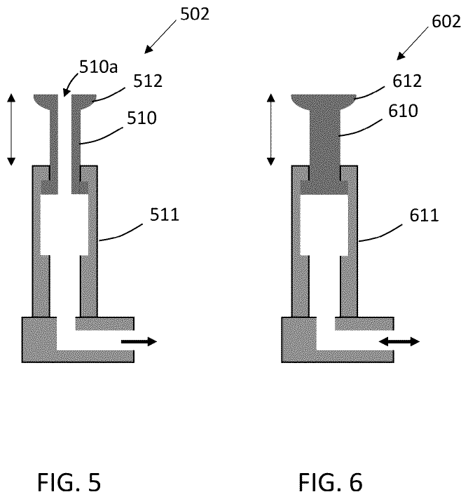

FIG. 5 shows an exemplary representation of a support pillar 502 according to an aspect of the present disclosure. The support pillar 502 may have a body 511 and a movable pin 510 with an upper portion 512 that may extend and retract from the body 511. The movable pin 510 may be coupled to a lifting actuator (not shown), which may be a component of the body 511, that pushes the movable pin 510 upward. As shown in FIG. 5, the movable pin 510 is a capillary with an opening 510a, which allows a negative pressure/suction may be applied through the movable pin 510a, when the upper portion 512 of the movable pin 510 is engaged with a landing feature (not shown) or other designated location (e.g., an unused space) and supporting a semiconductor panel (not shown). In another aspect, it may be possible to avoid the use of a lifting actuator (not shown) and have the suction pull a movable pin towards a landing feature.

FIG. 6 shows an exemplary representation of another support pillar 602 according to another aspect of the present disclosure. The support pillar 602 may have a body 611 and a movable pin 610 with an upper portion 612 that may extend and retract from the body 611. The movable pin 610 may be coupled to a lifting actuator (not shown), which may be a component of the body 611, or a pressure source that provides air, or a liquid such as oil, to push the movable pin 610 upward and when released causes the movable pin 610 to move downward.

In an aspect, the support pillars shown in FIGS. 5 and 6 may have bodies/barrels with diameters in a range of approximately 0.15 mm to 1.0 mm, and overall lengths as short as approximately 5 cm with a body/barrel length of approximately 3 cm. In an aspect, an upper portion of a movable pin may have a diameter that is equal to or greater than the diameter of the body/barrel of a support pillar depending on the type of landing feature on a semiconductor panel. In another aspect, the support pillars may have individual pressure valves (not shown) that may be incorporated into the body of the support pillar or positioned downstream from the support pillar. The pressure or suction provided to a support pillar may be calculated by simulations or determined by pre-production testing. The support pillars may be made of a metal, e.g., a copper alloy, or other durable materials. In yet another aspect, the present support pillars may have springs or coils in their bodies that are configured to engage their movable pins.

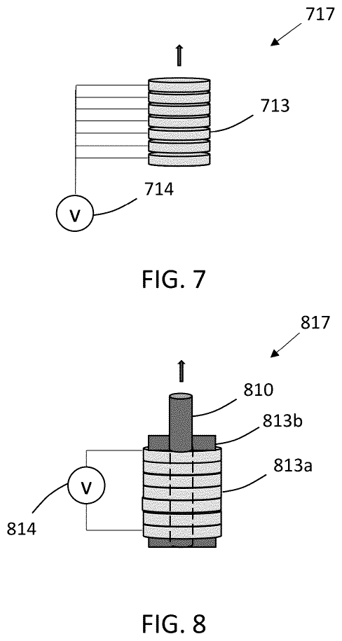

FIG. 7 shows an exemplary representation of a lifting actuator 717 according to an aspect of the present disclosure. The lifting actuator 717 may be a piezoelectric device, which is integrated into a body of a support pillar, that has a plurality of conductive members 713 connected to a voltage source 714. The plurality of conductive members 713 is provided with identical polarity, e.g., a positive polarity, that causes the plurality of conductive members 713 to repel each other, which will push a movable pin (not shown) upward.

FIG. 8 shows an exemplary representation of another lifting actuator 817 according to another aspect of the present disclosure. The lifting actuator 817 may be an electromagnetic device, which is integrated into a body of a support pillar, that has a conductive coil 813a and a core 813b connected to a voltage source 814. When a voltage is applied to the lifting actuator/electromagnetic device 817, a magnetic flux may be created that pushes a movable pin 810 upward.

It should be understood that it is within the scope of the present disclosure to use other lifting mechanisms in place of the lifting actuators shown in FIGS. 7 and 8. For example, it is also possible for a movable pin of a support pillar to be moved in the z-direction using air pressure, liquid pressure (e.g., oil), and mechanical devices (e.g., a motor).

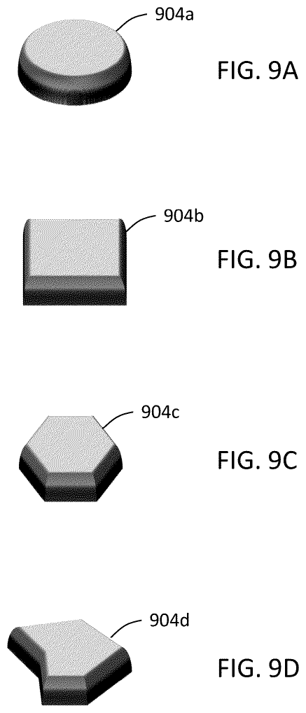

FIGS. 9A, 9B, 9C, and 9D show exemplary representations of landing pads according to aspects of the present disclosure. A present semiconductor panel may have a plurality of landing features including landing pads having a variety of shapes that are formed to engage with the support pillars of a support assembly. As shown in FIG. 9A, for example, a landing pad 904a may have a shape of a circle. In an aspect shown in FIG. 9B, for example, a landing pad 904b may have a shape of a rectangle. In another aspect shown in FIG. 9C, for example, a landing pad 904c may have a shape of a hexagon. In yet another aspect shown in FIG. 9D, for example, a landing pad 904d may have a shape of an irregular polygon. In a further aspect, the support pillars may have movable pins with upper portions that are complementary to the particular shapes of the landing features or landing pads. In an aspect, the thickness of a landing pad may be in a range of approximately 10 μm and 100 μm and may be made of metal (e.g., copper).

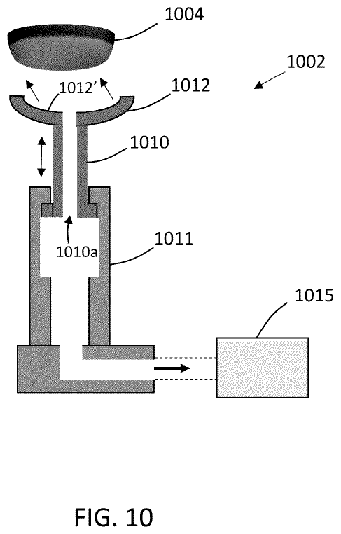

FIG. 10 shows an exemplary representation of a support pillar 1002 and a landing pad 1004 according to another aspect of the present disclosure. In this aspect, the support pillar 1002 may have a body 1011 and a movable pin 1010 with an upper portion 1012 having a support surface 1012′ for engaging with a semiconductor panel to provide a level position. As shown in FIG. 10, the movable pin 1010 is a capillary with an opening 1010a that is provided with suction from a vacuum unit 1015. In an aspect, the upper portion 1012 and the support surface 1012′ of the movable pin 1010 may have a shape that is complementary to the landing pad 1004 to provide better engagement with the landing pad 1004. In another aspect, the support pillar 1002 may be provided with sufficient flexibility in its body 1011 and movable pin 1010 to compensate for a minor misalignment between the upper portion 1012 of the movable pin 1010 and the landing pad 1004, including the complementary shape of the upper portion 1012, allowing it to slide over the rounded landing pad 1004. In an aspect, the moveable pin 1010 may have a starting position that is set by a controller to be in contact with the landing pad 1004, i.e., positioned in an extended position by a lifting actuator or an integrated spring.

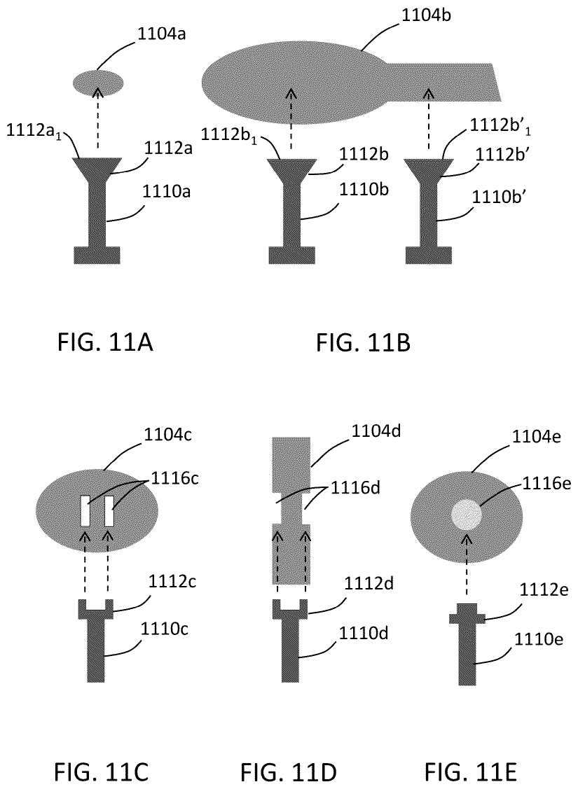

FIGS. 11A, 11B, 11C, 11D, and 11E show exemplary representations of different configurations for support pillars and landing pads according to an aspect of the present disclosure. As shown in FIG. 11A, for example, a landing feature 1104a may be a landing pad with a circular shape, and a complementary upper portion 1112a for a movable pin 1110a may have a flat support surface 1112a1 to engage the landing feature 1104a. In an aspect shown in FIG. 11B, for example, a landing feature 1104b may be a solder ball contact pad with a connecting metallization line, and complementary upper portions 1112b and 1112b′, respectively, for movable pins 1110b and 1110b′ may have flat support surfaces 1112b₁ and 1112b′₁, respectively, to engage the landing feature 1104b.

In another aspect shown in FIG. 11C, for example, a landing feature 1104c may have slots 1116c that provide a complementary shape to mate and engage with an upper portion 1112c for a movable pin 1110c. In yet another aspect shown in FIG. 11D, for example, a landing feature 1104d may have “structured” edges 1116d that provide a complementary shape to mate and engage with an upper portion 1112d for a movable pin 1110d. In a further aspect shown in FIG. 11E, for example, a landing feature 1104e may have a circular recess 1116e that provides a complementary shape to mate and engage with an upper portion 1112e for a movable pin 1110d.

It should be understood that it is within the scope of the present disclosure to use landing features that have different shapes beyond those shown in the drawings and to have support pillars with upper portions that have complementary shapes to engage those different shapes. In addition, the present landing features may be dedicated landing pads or other landing structures that may be “re-used” or be dual use (i.e., have another function in a semiconductor product being formed in the semiconductor panel such as a solder ball contact pad and/or a shielding area). The locations of the landing features may be placed on a semiconductor panel based on available free or unused locations in a semiconductor design layout.

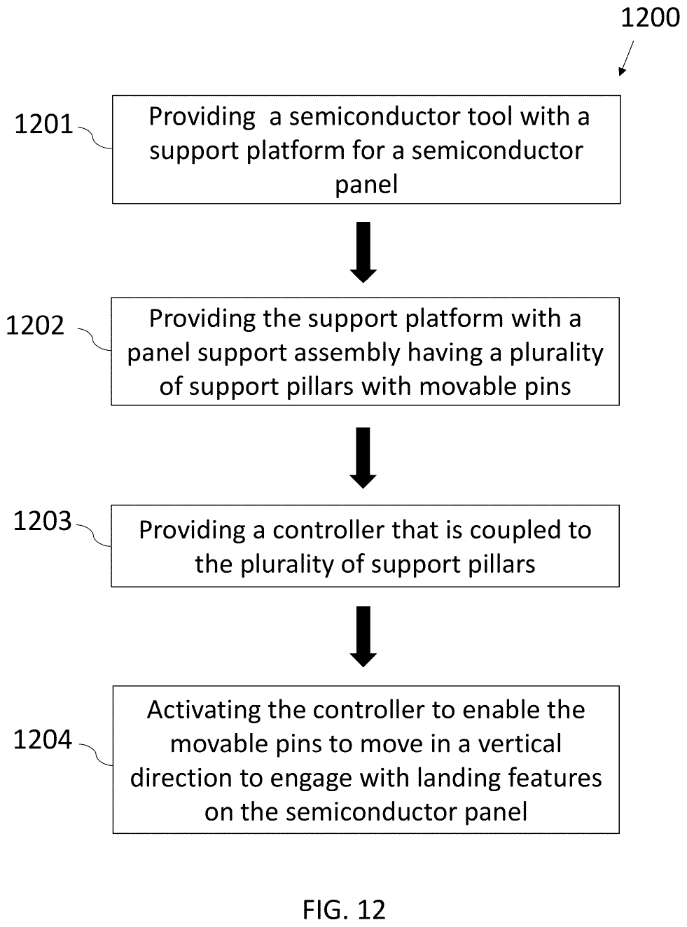

FIG. 12 shows a simplified flow diagram for an exemplary method 1200 according to an aspect of the present disclosure.

The operation 1201 may be directed to providing a semiconductor tool with a support platform for a semiconductor panel. The semiconductor panel may be pre-measured during production testing for warpage.

The operation 1202 may be directed to providing the support platform with a support assembly having a plurality of support pillars with movable pins.

The operation 1203 may be directed to providing a controller that is coupled to the plurality of support pillars.

The operation 1204 may be directed to activating the controller to enable the movable pins to move in a vertical direction to engage with landing features on the semiconductor panel.

It will be understood that any property described herein for a particular semiconductor tool having a support assembly and method for supporting a panel may also hold for any semiconductor tool using the present support assembly described herein. It will also be understood that any property described herein for a specific method may hold for any of the methods described herein. Furthermore, it will be understood that for any support assembly and the methods described herein, not necessarily all the components or operations described will be shown in the accompanying drawings or method, but only some (not all) components or operations may be disclosed.

To more readily understand and put into practical effect the semiconductor tool having present support assembly, they will now be described by way of examples. For the sake of brevity, duplicate descriptions of features and properties may be omitted.

### EXAMPLES

Example 1 provides a panel support assembly including a plurality of support pillars, for which each of the plurality of support pillars includes a body with a movable pin, for which the movable pin includes an upper portion with a support surface; and for which the panel support assembly is disposed in a semiconductor processing tool and the support face is positioned to contact a semiconductor panel placed in the semiconductor processing tool.

Example 2 may include the panel support assembly of example 1 and/or any other example disclosed herein, further includes a controller coupled to the support assembly, for which the controller is configured to enable each of the movable pins to move individually in a vertical direction to position the upper portion of the movable pin to support the semiconductor panel in a level position.

Example 3 may include the panel support assembly of example 1 and/or any other example disclosed herein, for which the plurality of support pillars is arranged as a regular grid.

Example 4 may include the panel support assembly of example 1 and/or any other example disclosed herein, for which the plurality of support pillars is arranged as an irregular grid.

Example 5 may include the panel support assembly of example 1 and/or any other example disclosed herein, for which the movable pin is a capillary that is coupled to a vacuum device.

Example 6 may include the panel support assembly of example 1 and/or any other example disclosed herein, for which each of the plurality of support pillars further includes a lifting actuator.

Example 7 may include the panel support assembly of example 6 and/or any other example disclosed herein, for which the lifting actuator includes a piezoelectric device.

Example 8 may include the panel support assembly of example 6 and/or any other example disclosed herein, for which the lifting actuator includes an electromagnetic device.

Example 9 may include the panel support assembly of example 1 and/or any other example disclosed herein, for which the support surface of the upper portion of the movable pin includes a shape that is complementary to a landing feature on the semiconductor panel, for which the landing feature includes a landing pad, a solder ball contact pad, and/or a metallization line.

Example 10 may include the panel support assembly of example 9 and/or any other example disclosed herein, for which the support surface of the movable pin is mateable with a complementary-shaped feature of the landing feature.

Example 11 provides a method that includes providing a semiconductor tool with a support platform, providing a support assembly with a plurality of support pillars on the support platform, and disposing a semiconductor panel on the support assembly, for which each of the plurality of support pillars includes a body with a movable pin, the movable pins comprises an upper portion that engages and supports the semiconductor panel, and for which the upper portions of the movable pins are alignable with landing features on the semiconductor panel.

Example 12 may include the method of example 11 and/or any other example disclosed herein, which further includes providing a controller configured to enable the movable pins to move individually in a vertical direction to engage with the landing features on the semiconductor panel to provide a level position.

Example 13 may include the method of example 12 and/or any other example disclosed herein, which further includes providing the controller with a warpage profile for the semiconductor panel and individually moving the movable pin in a vertical direction to engage with the landing features on the semiconductor panel according to the warpage profile.

Example 14 may include the method of example 12 and/or any other example disclosed herein, for which the controller activates a plurality of lifting actuators that causes the movable pins to move vertically upward to engage the landing features.

Example 15 may include the method of example 11 and/or any other example disclosed herein, which further includes providing a vacuum unit connected to the movable pin, for which the movable pin is a capillary, and suction is provided through the movable pin.

Example 16 provides a semiconductor tool including a support platform with a panel support assembly, the panel support assembly includes a plurality of support pillars, and each of the plurality of support pillars includes a body with a movable pin, and the movable pin includes an upper portion with a support surface, and for which the support face of the movable pin is configured to contact a semiconductor panel placed in the semiconductor processing tool.

Example 17 may include the semiconductor tool of example 16 and/or any other example disclosed herein, which further includes a controller coupled to the support assembly, for which the controller is configured to enable each of the movable pins to move individually in a vertical direction to position the upper portion of the movable pin to support the semiconductor panel in a level position.

Example 18 may include the semiconductor tool of example 17 and/or any other example disclosed herein, for which the controller is provided with a warpage profile for the semiconductor panel and individually moves the movable pin in a vertical direction, and for which the support surfaces of the movable pins contact a plurality of landing features on the semiconductor panel according to the warpage profile.

Example 19 may include the semiconductor tool of example 16 and/or any other example disclosed herein, for which the panel support assembly is configured to support the semiconductor panel being used for a specific semiconductor device.

Example 20 may include the semiconductor tool of example 16 and/or any other example disclosed herein, for which the semiconductor panel is disposed on a movable frame.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A panel support assembly comprising:
a plurality of support pillars, wherein each of the plurality of support pillars comprises a body with a movable pin, wherein the movable pin comprises an upper portion with a support surface; and wherein the panel support assembly is disposed in a semiconductor processing tool and the support surface of the movable pin configured to contact a semiconductor panel placed in the semiconductor processing tool.

2. The panel support assembly of claim 1, further comprising a controller coupled to the panel support assembly, wherein the controller is configured to enable each of the movable pins to move individually in a vertical direction to position the upper portion of the movable pin to support the semiconductor panel in a level position.

3. The panel support assembly of claim 1, wherein the plurality of support pillars is arranged as a regular grid.

4. The panel support assembly of claim 1, wherein the plurality of support pillars is arranged as an irregular grid.

5. The panel support assembly of claim 1, wherein the movable pin is a capillary that is coupled to a vacuum device.

6. The panel support assembly of claim 1, wherein each of the plurality of support pillars further comprises a lifting actuator.

7. The panel support assembly of claim 6, wherein the lifting actuator comprises a piezoelectric device.

8. The panel support assembly of claim 6, wherein the lifting actuator comprises an electromagnetic device.

9. The panel support assembly of claim 1, wherein the support surface of the movable pin comprises a shape that is complementary to a landing feature on the semiconductor panel,
wherein the landing feature comprises a landing pad, a solder ball contact pad, and/or a metallization line.

10. The panel support assembly of claim 9, wherein the support surface of the movable pin is mateable with a complementary-shaped feature of the landing feature.

11. A method comprising:
providing a semiconductor tool with a support platform;
providing a support assembly with a plurality of support pillars on the support platform; and
disposing a semiconductor panel on the support assembly,
wherein each of the plurality of support pillars comprises a body with a movable pin, the movable pin comprises an upper portion that engages and supports the semiconductor panel, and
wherein the upper portions of the movable pins are alignable with landing features on the semiconductor panel.

12. The method of claim 11, further comprising providing a controller configured to enable the movable pins to move individually in a vertical direction to engage with the landing features on the semiconductor panel to provide a level position.

13. The method of claim 12, further comprising providing the controller with a warpage profile for the semiconductor panel and individually moving the movable pin in a vertical direction to engage with the landing features on the semiconductor panel according to the warpage profile.

14. The method of claim 12, wherein the controller activates a plurality of lifting actuators that causes the movable pins to move vertically upward to engage the landing features.

15. The method of claim 11, further comprising providing a vacuum unit connected to the movable pin, wherein the movable pin is a capillary, and a suction is provided through the movable pin.

16. A semiconductor tool comprising:
a support platform with a panel support assembly, the panel support assembly comprising:
a plurality of support pillars, wherein each of the plurality of support pillars comprises a body with a movable pin, and the movable pin comprises an upper portion with a support surface, and
wherein the support face of the movable pin is configured to contact a semiconductor panel placed in the semiconductor processing tool.

17. The semiconductor tool of claim 16, further comprising a controller coupled to the panel support assembly, wherein the controller is configured to enable each of the movable pins to move individually in a vertical direction to position the upper portion of the movable pin to support the semiconductor panel in a level position.

18. The semiconductor tool of claim 17, wherein the controller is provided with a warpage profile for the semiconductor panel and individually moves the movable pins in a vertical direction, and wherein the support surfaces of the movable pins contact a plurality of landing features on the semiconductor panel according to the warpage profile.

19. The semiconductor tool of claim 16, wherein the panel support assembly is configured to support the semiconductor panel being used for a specific semiconductor device.

20. The semiconductor tool of claim 16, wherein the semiconductor panel is disposed on a movable frame.
